(19) United States
(12) Patent Application Publication
(10) Pub. No.: US 2003/0201806 A1
(43) Pub. Date: Oct. 30, 2003

(54) Duty cycle correction based frequency multiplier

(75) Inventor: Young-Kyun Cho, Suwon-city (KR)

Correspondence Address: Anthony P. Onello, Jr., MILLS & ONELLO LLP, Suite 605, Eleven Beacon Street, Boston, MA, 02108, US

(73) Assignee: Samsung Electronics Co., Ltd.

(21) Appl. No.: 10/394,959

(22) Filed: Mar. 21, 2003

(30) Foreign Application Priority Data
Apr. 25, 2002 (KR) 02-22727

(51) Int. Cl. H03B 19/00

(52) U.S. Cl. 327/116

(57) ABSTRACT

A frequency multiplier and method of frequency multiplication overcome the shortcomings of those frequency multiplication systems and methods that utilize a phase locked loop or a delay locked loop, and occupy smaller chip area and consume less power when embodied in an integrated circuit. A first duty cycle correction circuit receives a first signal and generates a second signal, the frequency of which is the same as that of the first signal and the duty cycle of which is 50:50. An edge detector detects edges of the second signal and generates a third signal corresponding to the detected edges. In an optional embodiment, a second duty cycle correction circuit receives the third signal and generates a fourth signal, the frequency of which is the same as that of the third signal and the duty cycle of which is 50:50. Since the frequency multiplier and the method of multiplying frequencies utilize relatively simple circuits without the need for using a phase locked loop or a delay locked loop, it is possible to prevent the problems of jitter and false locks.

### BACKGROUND OF THE INVENTION

This application claims the priority of Korean Patent Application No. 2002-22727, filed Apr. 25, 2002 in the Korean Intellectual Property Office, which is incorporated herein in its entirety by reference.

1. Field of the Invention

The present invention relates to a frequency multiplier, for example a frequency doubler, and more particularly, to a duty cycle correction based frequency multiplier.

2. Description of the Related Art

Oscillators are commonly used in systems in order to provide a clock signal having a predetermined frequency. In general, a crystal oscillator, which utilizes the mechanical characteristics of crystal, becomes more expensive as the frequency of a clock signal which is generated from the crystal oscillator becomes higher.

Recently, a method for multiplying frequencies has been used in order to obtain a clock signal having a predetermined frequency wherein a phase locked loop or a delay locked loop is used for multiplying frequencies. Because the phase locked loop comprises a voltage controlled oscillator VCO, jitter can occur. On the other hand, the delay locked loop is subject to the shortcoming of false locks. In addition, since the phase locked loop and the delay locked loop are both embodied in complicated circuits, they require a large chip area and power consumption, if they are to be included in an integrated circuit.

### SUMMARY OF THE INVENTION

The present invention provides a frequency multiplier which overcomes the shortcomings of frequency multipliers that employ a phase locked loop or a delay locked loop. The frequency multiplier of the present invention further offers the advantages of a relatively small chip area and low power consumption when it is embodied in an integrated circuit.

The present invention further provides a method of frequency multiplication which overcomes the shortcomings of techniques that rely on a phase locked loop or delay locked loop, and further offers the advantages of reduced chip area and power consumption when it is embodied in an integrated circuit.

According to an aspect of the present invention, there is provided a frequency multiplier comprising a first duty cycle correction circuit which receives a first signal and generates a second signal, the frequency of the second signal being the same as that of the first signal and having a duty cycle of which is 50:50 and an edge detector which detects edges of the second signal and generates a third signal corresponding to the detected edges.

It is preferable that the first duty cycle correction circuit comprises a voltage controlled duty cycle corrector, a duty cycle comparator, and a filter. Here, the voltage controlled duty cycle corrector changes the duty cycle of the first signal in response to a level of a control voltage. The duty cycle comparator checks if a duty cycle of an output signal of the voltage controlled duty cycle corrector is 50:50. The filter controls the level of the control voltage in response to the output signal of the duty cycle comparator.

The frequency multiplier according to the present invention may further comprise a second duty cycle correction circuit which receives the third signal and generates a fourth signal, the frequency of the fourth signal being the same as that of the third signal and the fourth signal having a duty cycle that is 50:50,

According to another aspect of the present invention, there is provided a method of multiplying a frequency of a signal, comprising receiving a first signal and generating a second signal, the second signal having a frequency that is the same as that of the first signal and having a duty cycle that is 50:50; and detecting edges of the second signal and generating a third signal corresponding to the detected edges.

The generation of the second signal comprises changing the duty cycle of the first signal in response to a level of a control voltage, determining whether the duty cycle of the first signal is 50:50, changing the duty cycle again by controlling the level of the control voltage if the duty cycle of the first signal is not 50:50 according to the determination result, and outputting the first signal as the second signal if the duty cycle of the first signal is 50:50 according to the determination result.

The method of multiplying frequencies may further comprise receiving the third signal and generating a fourth signal, a frequency of which is the same as that of the third signal and a duty cycle of which is different from that of the third signal. When the duty cycle of the fourth signal is 50:50, the generation of the fourth signal is performed in the same manner as the generation of the second signal.

### BRIEF DESCRIPTION OF THE DRAWINGS

The above objects and advantages of the present invention will become more apparent by describing in detail preferred embodiments thereof with reference to the attached drawings in which:

FIG. 1 is a block diagram depicting a frequency multiplier according to an embodiment of the present invention; and

FIG. 2 is a timing diagram depicting the operation of a frequency multiplier according to the embodiment of the present invention shown in FIG. 1.

### DETAILED DESCRIPTION OF PREFERRED EMBODIMENTS

The present invention will now be described more fully with reference to the accompanying drawings, in which preferred embodiments of the invention are shown. The same reference numerals in different drawings represent the same elements.

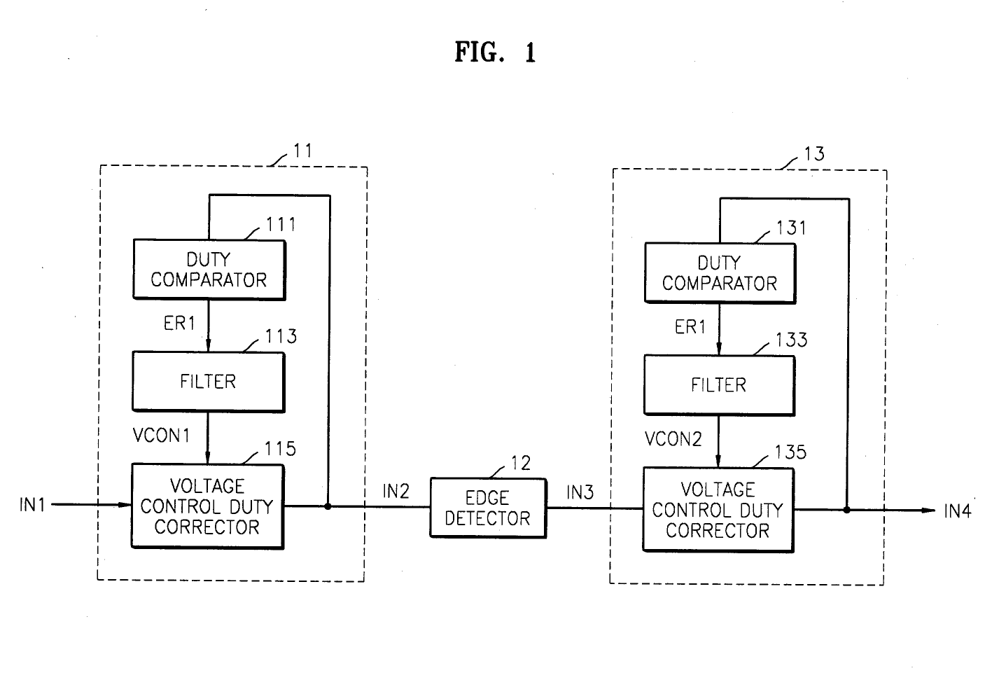

FIG. 1 is a block diagram of a frequency multiplier according to an embodiment of the present invention. Referring to FIG. 1, a frequency multiplier according to an embodiment of the present invention comprises a first duty cycle correction circuit 11, which receives a first signal IN1, and generates a second signal IN2, the frequency of which is the same as that of the first signal, and has a duty cycle of 50:50, and an edge detector 12 which detects rising and falling edges of the second signal IN2 and generates a third signal IN3 corresponding to the detected edges.

The frequency multiplier according to an embodiment of the present invention optionally further comprises a second duty cycle correction circuit 13, which receives a third signal IN3 and generates a fourth signal IN4, the frequency of which is the same as that of the third signal, and has a duty cycle of 50:50. If the duty cycle of the fourth signal IN4 is 50:50, the second duty cycle correction circuit 13 can be formed in the same configuration as the first duty cycle correction circuit 11 as shown in FIG. 1.

The first duty cycle correction circuit 11 comprises a duty cycle comparator 111, a filter 113, and a voltage controlled duty cycle corrector 115. The voltage controlled duty cycle corrector 115 changes the duty cycle of the first signal IN1 in response to the level of a control voltage VCON1 provided by the filter 113. The duty cycle comparator 111 determines whether the output signal of the voltage controlled duty cycle corrector 115, i.e. the second signal IN2, has a duty cycle of 50:50. The filter 113 controls the level of the control voltage VCON1 in response to an output signal ER1 of the duty cycle comparator 111.

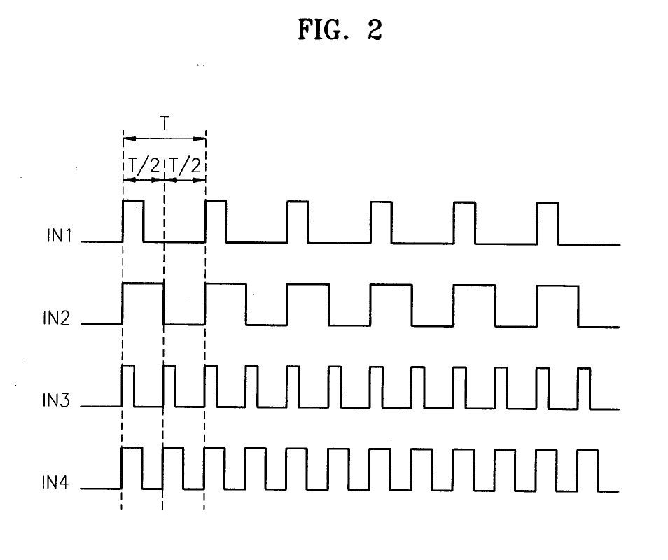

FIG. 2 is a timing diagram showing the operation of a frequency multiplier according to the embodiment of the present invention shown and described above with reference to FIG. 1. The operation of the frequency multiplier shown in FIG. 1 and the method of multiplying a frequency according to the present invention are described in detail with reference to FIG. 2.

The first duty cycle correction circuit 11 receives a first signal IN1, the period of which is not T and the duty cycle of which is not 50:50, corrects the duty cycle of the first signal IN1, and generates a second signal IN2, the period of which is the same as that of the first signal IN1 and the duty cycle of which is 50:50:

To be more specific, the voltage controlled duty cycle corrector 115 in the first duty cycle correction circuit 11 changes the duty cycle of the first signal IN1 in response to the level of the control voltage VCON1 provided by the filter 113. Next, the duty cycle comparator 111 determines whether the output signal of the duty cycle corrector 115, i.e. the duty cycle of the second signal IN2, is 50:50.

If the duty cycle of the second signal IN2 according to the comparison result is not 50:50, the filter 113 modifies the level of the control voltage VCON1 in response to the error signal ER1 provided by the duty cycle comparator 111 and modifies the duty cycle of the first signal IN1 in response to the level-controlled control voltage VCON1. The above process is repeatedly performed until the duty cycle of the second signal IN2 becomes 50:50.

If the second signal IN2 reaches a duty cycle of 50:50, a feedback loop formed by the duty cycle comparator 111, the filter 113, and the voltage controlled duty cycle corrector 115 is locked, and a second signal IN2 of the voltage controlled duty cycle corrector 115, the duty cycle of which is 50:50, is continuously output from the voltage controlled duty cycle corrector 115.

Next, the edge detector 12 detects rising edges and falling edges of the second signal IN2, and generates a third signal IN3 corresponding to the detected edges. The edge detector generates a short-duration pulse as the third signal IN3 at each detected edge of the input second signal IN2. Thus, the period of the third signal IN3 becomes half of the period T of the first signal IN1. In other words, the frequency of the third signal IN3 becomes double that of the first signal IN1.

Meanwhile, as shown in FIG. 1, in a frequency multiplier further comprising the optional second duty cycle correction circuit 13 according to the present invention, the second duty cycle correction circuit 13 receives the third signal IN3, the period of which is T/2 and a duty cycle of which is not necessarily 50:50, corrects the duty cycle of the third signal IN3, and generates a fourth signal IN4, the period of which is the same as that of the third signal IN3 and the duty cycle of which is 50:50.

The second duty cycle correction circuit 13 operates in the same manner as the first duty cycle correction circuit 11. To be more specific, the voltage controlled duty cycle corrector 135 in the second duty cycle correction circuit 13 modifies the duty cycle of the input third signal IN3 in response to the level of the control voltage VCON2 provided by the filter 133. Next, the duty cycle comparator 131 determines whether the output signal of the voltage controlled duty cycle corrector 135 or the duty cycle of the fourth signal IN4 is 50:50.

If the duty cycle of the fourth signal IN4 according to the comparison result is not 50:50, the filter 133 controls the level of the control voltage VCON2 in response to the error signal ER2 provided by the duty cycle comparator 131, and modifies the duty cycle of the third signal IN3 in response to the level-controlled control voltage VCON2. The above process is repeatedly performed until the duty cycle of the fourth signal IN4 becomes 50:50.

If the fourth signal IN4 reaches a duty cycle of 50:50, a feedback loop formed by the duty cycle comparator 131, the filter 133, and the duty cycle corrector 135 becomes locked, and a fourth signal IN4 of the voltage controlled duty cycle corrector, a duty cycle of which is 50:50, is continuously output from the voltage controlled duty cycle corrector 135. Thus, the frequency of the fourth signal IN4 becomes double that of the first signal IN1 and the duty cycle of the fourth signal IN4 becomes 50:50.

Meanwhile, it is possible to repeatedly connect additional stages of edge detectors and duty cycle correction circuits to an output stage of the second duty cycle correction circuit 13 in order to obtain a signal having a higher frequency, and a duty cycle of which is 50:50.

While this invention has been particularly shown and described with reference to preferred embodiments thereof, it will be understood by those skilled in the art that various changes in form and details may be made therein without departing from the spirit and scope of the invention as defined by the appended claims.

As described above, a frequency multiplier and a method of multiplying a frequency using the frequency multiplier according to the present invention utilizes relatively simple circuits without the need for utilizing a phase locked loop or a delay locked loop. Accordingly, it is possible to prevent the problems associated with jitter or false lock that can occur in a conventional frequency multiplier using a phase locked loop or a delay locked loop. In addition, the present invention consumes relatively small chip area and power consumption, as compared to a conventional frequency multiplier using a phase locked loop or a delay locked loop.

What is claimed is:

1. A frequency multiplier comprising:
a first duty cycle correction circuit which receives a first signal and generates a second signal, the second signal having a frequency that is the same as that of the first signal and having a duty cycle that is 50:50; and
an edge detector which detects edges of the second signal and generates a third signal corresponding to the detected edges.

2. The frequency multiplier of claim 1, wherein the first duty cycle correction circuit comprises:
a voltage controlled duty cycle corrector which modifies the duty cycle of the first signal in response to a level of a control voltage;
a duty cycle comparator which determines whether a duty cycle of an output signal of the voltage controlled duty cycle corrector is 50:50; and
a filter which controls the level of the control voltage in response to the output signal of the duty cycle comparator.

3. The frequency multiplier of claim 1, wherein the frequency multiplier further comprises a second duty cycle correction circuit which receives the third signal and generates a fourth signal, the fourth signal having a frequency that is the same as that of the third signal and having a duty cycle that is different from that of the third signal.

4. The frequency multiplier of claim 1, wherein the frequency multiplier further comprises a second duty cycle correction circuit which receives the third signal, and generates a fourth signal, the fourth signal having a frequency that is the same as that of the third signal and having a duty cycle that is 50:50.

5. The frequency multiplier of claim 4, wherein the second duty cycle correction circuit comprises:
a voltage controlled duty cycle corrector which modifies the duty cycle of the third signal in response to a level of a control voltage;
a duty cycle comparator which determines whether a duty cycle of an output signal of the voltage controlled duty cycle corrector is 50:50; and
a filter which controls the level of the control voltage in response to an output signal of the duty cycle comparator.

6. A method of multiplying a frequency of a signal, the method comprising:
receiving a first signal and generating a second signal, the second signal having a frequency that is the same as that of the first signal and having a duty cycle that is 50:50; and
detecting edges of the second signal and generating a third signal corresponding to the detected edges.

7. The method of multiplying a frequency of a signal of claim 6, wherein generating the second signal comprises:
modifying the duty cycle of the first signal in response to a level of a control voltage;
determining whether the duty cycle of the first signal is 50:50;
modifying the duty cycle of the first signal by controlling the level of the control voltage if the duty cycle of the first signal is not 50:50 according to the result of the determination; and
outputting the first signal as the second signal if the duty cycle of the first signal is 50:50 according to the result of the determination.

8. The method of multiplying a frequency of a signal of claim 6, further comprising receiving the third signal and generating a fourth signal, the fourth signal having a frequency that is the same as that of the third signal and the fourth signal having a duty cycle that is different from that of the third signal.

9. The method of multiplying a frequency of a signal of claim 6, further comprising receiving the third signal and generating a fourth signal, the fourth signal having a frequency that is the same as that of the third signal and the fourth signal having a duty cycle that is 50:50.

10. The method of multiplying a frequency of a signal of claim 9, wherein generating the fourth signal comprises:
modifying the duty cycle of the third signal in response to a level of a control voltage;
determining whether the duty cycle of the third signal is 50:50;
modifying the duty cycle of the third signal by controlling the level of the control voltage if the duty cycle of the third signal is not 50:50 according to the result of the determination; and
outputting the third signal as the fourth signal if the duty cycle of the third signal is 50:50 according to the result of the determination.
